(19) United States
(12) Patent Application Publication
(10) Pub. No.: US 2013/0323407 A1
(43) Pub. Date: Dec. 5, 2013

(54) METHOD FOR COATING WITH AN EVAPORATION MATERIAL

(71) Applicant: Leica Mikrosysteme GmbH, Vienna (AT)

(72) Inventors: Paul WURZINGER, Deutsch Wagram (AT); Anton LANG, Vienna (AT)

(21) Appl. No.: 13/906,469

(22) Filed: May 31, 2013

(30) Foreign Application Priority Data
Jun. 4, 2012 (AT) A50219/2012

(51) Int. Cl. C23C 16/448

(52) U.S. Cl. CPC C23C 16/4485
USPC 427/10; 118/665

(57) ABSTRACT

An apparatus for depositing a material layer on a sample inside a vacuum chamber comprises a sample stage (100) for arranging at least one sample (103a, 103b, 103c, 103d); an evaporation source (101, 201), connected to a current source, for a thread-shaped evaporation material (102, 202); a quartz oscillator (105) for measuring the deposited material layer thickness; and an evaluation device (113) associated with the oscillator (105). An electronic control system (112) associated with the evaporation source (101, 201) is configured to deliver electric current in the form of at least two current pulses having a pulse length less than or equal to 1 s. The evaluation device (113) takes into account transient decay behavior of the oscillator (105) immediately after a current pulse to derive the material layer thickness deposited after each pulse. The invention further relates to a method that can be carried out using said apparatus.

### CROSS REFERENCE TO RELATED APPLICATIONS

This application claims priority of Austrian patent application number A50219/2012 filed Jun. 4, 2012, the entire disclosure of which is incorporated by reference herein.

### FIELD OF THE INVENTION

The invention relates to an apparatus for depositing a material layer on a sample inside a vacuum chamber, comprising a sample stage for arranging at least one sample; an evaporation source, connected to a current source, for a thread-shaped evaporation material; a quartz oscillator for measuring the deposited material layer thickness; and an evaluation device associated with the quartz oscillator. The invention further relates to a method that can be carried out with said apparatus.

### BACKGROUND OF THE INVENTION

The vaporization of thin thread-shaped evaporation materials by heating with electric current in a vacuum evaporation apparatus has been used for a long time to coat electron microscopy substrates and prepared samples. Prior to investigation in a scanning electron microscope (SEM), nonconductive samples and materials are coated with a conductive material, usually gold or carbon. The known method of carbon thread evaporation is widely used in electron microscopy, in particular in the manufacture of impression films and reinforcing films for transmission electron microscopy, and very thin conductive surface layers for scanning electron microscopy samples. In the context of X-ray microanalysis carried out in SEM, encompassing energy-dispersive X-ray analysis (EDX) and wavelength-dispersive X-ray analysis (WDX), the sample is first vapor-coated with a very thin layer of carbon. A very thin layer of carbon deposited on the sample is also needed in the electron backscatter diffraction method (EBSD), a crystallographic technique used in scanning electron microscopy.

Vacuum evaporation apparatuses for thermal evaporation of thread-shaped evaporation materials, as known from the existing art, typically comprise a vacuum chamber in which a sample receptacle/sample stage having the sample to be vapor-coated, and an evaporation source connected to a current source, are arranged. The sample is vapor-coated vertically or obliquely; the evaporated material strikes the surface of the sample, mounted horizontally on the sample stage, at a predefined angle with respect to the horizontal plane.

Flash-type evaporation (also known as the “flash method” or “flash evaporation”) of a thin carbon thread by heating with a high current flow is commonly used to coat specimens, and is notable for simple handling and little thermal stress on the sample. Flash evaporation often results in abrupt breakage of the carbon-thread residue, in which context unevaporated threads and particles can travel onto the sample and contaminate it. The layer thickness and layer thickness distribution are moreover defined by the geometric correlations between the sample and the evaporation source as well as the thread thickness, and can be varied to only a limited extent by using different thread thicknesses and by varying the distance between the evaporation source and the samples. A further disadvantage of the flash method is that the carbon thread breaks and must be replaced by a new carbon thread. Such changes are time-consuming and result in lower equipment utilization, lower sample throughput, and consequently lower cost-effectiveness.

In modified methods the current flow is time-limited (pulsed), so that the entire carbon thread is not evaporated during a pulse. The pulses are limited by brief manual switching or by electronic control. As a rule, several pulses are necessary in order to evaporate the entire carbon thread segment. In the pulsed method, the volume of carbon thread that is actually evaporated can vary greatly, since different thread segments develop different resistance values after partial evaporation. Because the carbon thread does not break, and also remains mechanically stable, in the case of pulsed methods, the quantity deposited is less than with the flash method. The quantity deposited per pulse also varies, since the carbon thread heats up less as resistance increases. When the pulses are switched manually there is also a variation over time in the pulses. Only poorly defined layer thicknesses can therefore be obtained with the previously known methods based on current pulses.

Measuring the layer thickness of a deposited layer using a quartz oscillator has likewise been known for some time, measurement accuracy being negatively affected chiefly by sensitivity to environmental influences such as temperature, surface coverage with condensable substances, mechanical stress, inhomogeneous heating, etc. Layer thickness measurement using a quartz oscillator is also greatly impaired by the radiation (light and heat) proceeding from the carbon thread during evaporation. Because of these facts, layer thickness measurement using a quartz oscillator in a carbon evaporation process is therefore usable at most in order to check reproducibility, but not for accurate measurement of the deposited layer thickness or to limit the coating operation.

The layer thickness, homogeneity, and electrical conductivity of a carbon layer are of the greatest importance for electron microscopy applications. For most electron microscopy applications it is therefore essential that the coatings evaporated onto the electron microscopy substrates and prepared samples not exceed or fall below a predetermined thickness. Insufficiently controlled material deposition, and a resulting inhomogeneity in layer thickness, have a considerable effect on the quality of the prepared sample and thus on the image resolution quality. A reproducible layer thickness of the highest accuracy is particularly desirable for the aforementioned EDX/WDX and EBSD analysis in combination with SEM.

### SUMMARY OF THE INVENTION

It is therefore an object of the invention to improve the above-described methods of thread evaporation so that their advantages, such as simple handling and low thermal stress on samples, are retained, but the disadvantages known from the existing art, such as susceptibility to contamination and inaccurate layer thickness measurement, are eliminated. A further object of the invention is to provide an apparatus for carrying out the improved evaporation method.

This object is achieved with an apparatus for depositing a material layer on a sample inside a vacuum chamber as recited earlier, the apparatus being characterized according to the present invention in that an electronic control system is associated with the evaporation source and is configured to deliver to the evaporation source the electric current provided by the current source in the form of at least two current pulses having a pulse length less than or equal to 1 s; and that the evaluation device is configured to take into account the transient decay behavior of the quartz oscillator immediately after completion of a current pulse in order to derive the material layer thickness deposited after each current pulse.

This object is further achieved by a method for depositing a material layer on at least one sample inside a vacuum chamber, the method being characterized by the steps of:
evaporating at least a segment of a thread-shaped evaporation material by heating by means of electric current, the current being delivered to the thread-shaped evaporation material in at least two current pulses having a pulse length less than or equal to 1 s, the current pulses being selected so that the thread-shaped evaporation material does not break,
measuring the material layer thickness deposited after a current pulse by means of a quartz oscillator, taking into account the transient decay behavior of the quartz oscillator immediately after completion of a current pulse.

The invention makes possible a well-defined variation in layer thickness by measuring the layer thickness of evaporated material deposited with each current pulse. The influence on the signal of the quartz measurement crystal during the current pulse as a result of radiation (light and heat) is taken into account according to the present invention for accurate measurement of the layer thickness. It is thereby possible to determine with high accuracy the thickness of the layer deposited during a pulse, and to establish the desired total layer thickness. With the invention, layers can be obtained over a wide range of layer thicknesses, beginning at very low layer thicknesses of less than 1 nm up to large layer thicknesses of 20 nm or more, within a narrow tolerance band. The identified thicknesses of the individual layers are added up until the process ends when the desired total layer thickness is reached. The invention further makes possible better reproducibility of the coating.

Because the current pulses are selected so that the thread-shaped evaporation material does not break, in contrast to the above-described flash methods the risk of contamination can be excluded. The pulse data selected for this depend on the thread material used. They can be identified, by means of simple routine experiments, as a function of the deposition thickness desired for each pulse. One skilled in this art will also have no difficulty transferring to the disclosed method data that are known to him or her from other similar methods.

The term “thread-shaped evaporation material” refers to all thread-shaped materials that are suitable for thermal evaporation in a vacuum evaporation apparatus and are known to one skilled in the relevant art. The evaporation material can be, for example, carbon (graphite) or tungsten, but all materials, metals, and alloys that develop an appreciable vapor pressure in solid form (e.g. silver) are appropriate.

The apparatus and the method according to the present invention are particularly advantageous for applying a carbon layer having a well-defined thickness onto an electron microscopy specimen, in particular for the application of very thin carbon layers with an accuracy of approx. 0.5 nm, such as those necessary for X-ray microanalysis (EDX/WDX) and EBSD analysis in combination with SEM. In a preferred embodiment of the invention, the thread-shaped evaporation material is therefore a carbon thread (graphite thread). Twisted or braided carbon threads having a thickness from 0.2 g/m to 2 g/m can, in particular, be utilized.

The method is typically carried out under vacuum, in which context the vacuum should preferably be better than 1×10⁻² mbar. The at least one sample is preferably an electron microscopy prepared sample.

It is possible in principle, utilizing corresponding holding apparatuses known per se to one skilled in the relevant art, to use all quartz oscillators that are usual for layer thickness measurements (e.g. AT, SC, RC orientation designations). Quartz crystals having the AT orientation are preferably used, since they exhibit the best temperature behavior at room temperature and need not be kept at an elevated temperature. The quartz wafers preferably have a diameter of approx. 14 mm, a thickness of approx. 0.2 mm, and are metallized on both sides.

In a preferred method variant, measurement of the material layer thickness occurs immediately after completion of each current pulse. This is advantageous in particular for thinner layer thicknesses with high accuracy and a narrow tolerance band in terms of the layer thickness distribution.

In a further method variant, in the context of the production of thick layers the layer thickness measurement can also occur after multiple pulses, with the result that the entire process is accelerated.

According to the present invention, the transient decay behavior of the quartz oscillator after completion of a current pulse is taken into account when measuring the deposited material thickness. In a first preferred embodiment, the signal of the quartz oscillator is allowed to decay to a baseline level before the material layer thickness is measured. This baseline level is usually attained 4 to 5 seconds after completion of the current pulse. Usefully, the material layer thickness is identified from the difference between the baseline level of the quartz oscillator signal before deposition of the material layer and the baseline level of the quartz oscillator signal after deposition of the material layer. A quartz oscillator typically oscillates at a frequency of 5 to 6 MHz. The deposition of material onto the quartz oscillator surface results in a change in the resonant frequency. The difference between the baseline level of the quartz oscillator signal before deposition of the material layer and the baseline level of the quartz oscillator signal after deposition of the material layer is in the Hz range, for example the measured difference for a carbon layer 1 nm thick is typically approx. 15 Hz.

Alternatively to the aforementioned embodiment, in a further advantageous embodiment the decaying signal of the quartz oscillator is adapted or “fitted” using a suitable function (of exp⁻¹ type), and a sufficiently accurate measurement is therefore already achieved during the decay time. The material layer thickness is consequently measured by utilizing the following steps:
measuring the curve for the frequency of the quartz oscillator as a function of time,
adapting to that curve a parameterized function that is parameterized with at least one parameter, and
deriving a material layer thickness from the at least one parameter.

The parameter to be adapted has a unique functional relationship to the baseline level to which the transient decay behavior is heading; a proportionality preferably exists. The time constant of the decay process can be adapted as a further parameter.

The electronic control system sends current pulses through at least a segment of the thread-shaped evaporation material in order to heat the latter in such a way that the material of the thread evaporates off and becomes deposited as a layer on the sample. The current pulses are selected so that the thread segment only partly evaporates and does not under any circumstances break. The current pulses are furthermore selected so that for each thread segment, at least two current pulses can be carried out before the resistance of the thread has become so high (as a result of evaporation of the evaporation material) that the current flow is no longer sufficient for further evaporation. Advantageously, the pulse length of a current pulse is 20 ms to 1 s, preferably 50 ms to 500 ms. The current intensity of a current pulse is advantageously selected so that it is from 6 A to 50 A. A sufficiently known variety of electronic control devices for generating current pulses having the aforementioned pulse data is available to one skilled in the art. The electronic control system usefully regulates the current by current limiting upon application of a maximum voltage, by direct current regulation, or by adaptive adjustment of the voltage to the resistance measured in the preceding current pulse.

The electronic control system is preferably capable of directly measuring, controlling, and/or switching the current flow even at full power using solid-state components, for example power semiconductor transistors, and can dispense with mechanical switching elements such as power relays.

In an aspect of the invention, the layer inhomogeneities determined by the evaporation geometry are equalized by changing the positioning of the at least one sample in terms of its position with respect to the thread-shaped evaporation material that is to be evaporated and is received in the evaporation source. This is particularly advantageous when two or more samples are simultaneously present in the vacuum chamber and are being processed. In a subsidiary aspect, the change in the positioning of the at least one sample occurs preferably between two successive current pulses. The one or more samples are thus displaced, for each current pulse, in such a way that the layer distribution determined by the evaporation geometry is equalized. The result is that a very uniform and well-defined layer thickness is achieved even with very thin coatings. This is of particular significance in the context of the aforementioned X-ray analysis (EDX/WDX) as well as in EBSD analysis in combination with SEM. In addition, with this method variant more than one sample can be equipped simultaneously with a uniform material coating, thereby achieving higher efficiency and better equipment utilization. In order to determine the layer thickness exactly, the geometrical conditions are taken into account and the layer effectively deposited onto the samples is calculated on the basis of the layer thickness measured using the quartz oscillator. The ratio of the distances between the sample and carbon thread, and between the quartz sensor and carbon thread (substantially square distance law), and the inclination of the quartz sensor with respect to the source (cosine law) are taken into account. A measured tabular function, or a function identified by measurement and parametrically corrected for specific positions with respect to the aforesaid laws, is preferably used, since shadowing and reflection effects can thereby also be considered.

In order to implement the above-described aspect of equalizing layer inhomogeneities by changing the positioning of the at least one sample in terms of its position with respect to the thread-shaped evaporation material, the at least one sample is received in the apparatus according to the present invention on a motor-driven movable sample stage. In an embodiment of the apparatus, the sample stage for positioning the at least one sample with reference to the position of the evaporation source is therefore embodied as a switchable stage movable by a motor. In a subsidiary variant, the sample stage comprises a turntable rotatable around a rotation axis, at least two samples being arranged on the rotatable turntable. The samples are preferably arranged on the turntable offset at identical angles from one another. In another variant the samples are arranged only on a portion of the turntable. The quartz oscillator is preferably arranged at the center of the turntable.

In an embodiment, the evaporation source comprises a holder, comprising at least two electrical feedthroughs, for the thread-shaped evaporation material. Control is applied to the electrical feedthroughs via the electronic control system so that the thread-shaped evaporation material that is received between the electrical feedthroughs in the vacuum chamber is heated by the released current pulses and is thereby evaporated. When multiple samples are being coated, or when thicker layer thicknesses are being applied, the material deposited by only one thread segment may be too little. In order to allow more than one thread segment to be evaporated, it is advantageous if the holder for the thread-shaped evaporation material comprises at least three, preferably at least five electrical feedthroughs. With at least five electrical feedthroughs, at least four thread segments can be provided. The electronic control system applies control in each case to one adjacent pair of feedthroughs so that only the respective thread segment that is received between that pair of feedthroughs is energized and evaporated. When the resistance of a thread segment has become so high, as a result of evaporation of the material, that the current flow is no longer sufficient for further evaporation, the sample stage is typically readjusted in order to correct the geometric offset of the two thread segments. Alternatively thereto, the holder of the evaporation source can also be arranged displaceably in the vacuum chamber.

Preferably at least one of the at least one sample is arranged at a distance of 30 mm to 100 mm from the evaporation source. The at least one sample is received on the sample stage in a suitable sample receptacle that is known per se to one skilled in the art.

### BRIEF DESCRIPTION OF THE DRAWING VIEWS

The invention, together with further advantages, will be explained in further detail below with reference to a non-limiting example that is depicted in the appended drawings, in which:

FIG. 1 schematically depicts an arrangement having a motorized sample stage that is associated with apparatuses according to the present invention and is arranged eccentrically with respect to an evaporation source,

FIG. 2 shows an evaporation source having five electrical feedthroughs for a total of four carbon thread segments,

FIG. 3 schematically depicts the arrangement of FIG. 1 arranged in a vacuum chamber,

FIG. 4 shows a transient decay function of a quartz oscillator, and

FIG. 5 is a flow chart to illustrate a process sequence for coating by means of carbon thread evaporation.

### DETAILED DESCRIPTION OF THE INVENTION

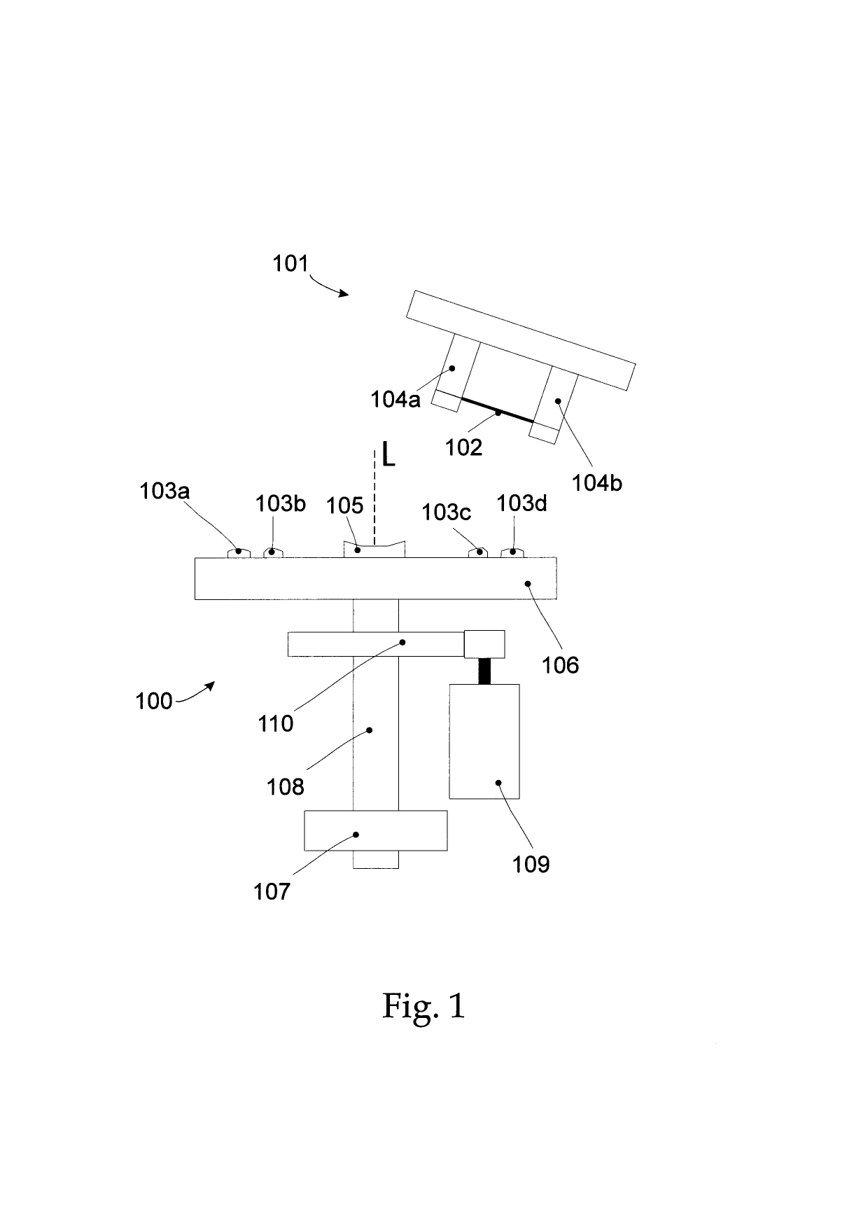

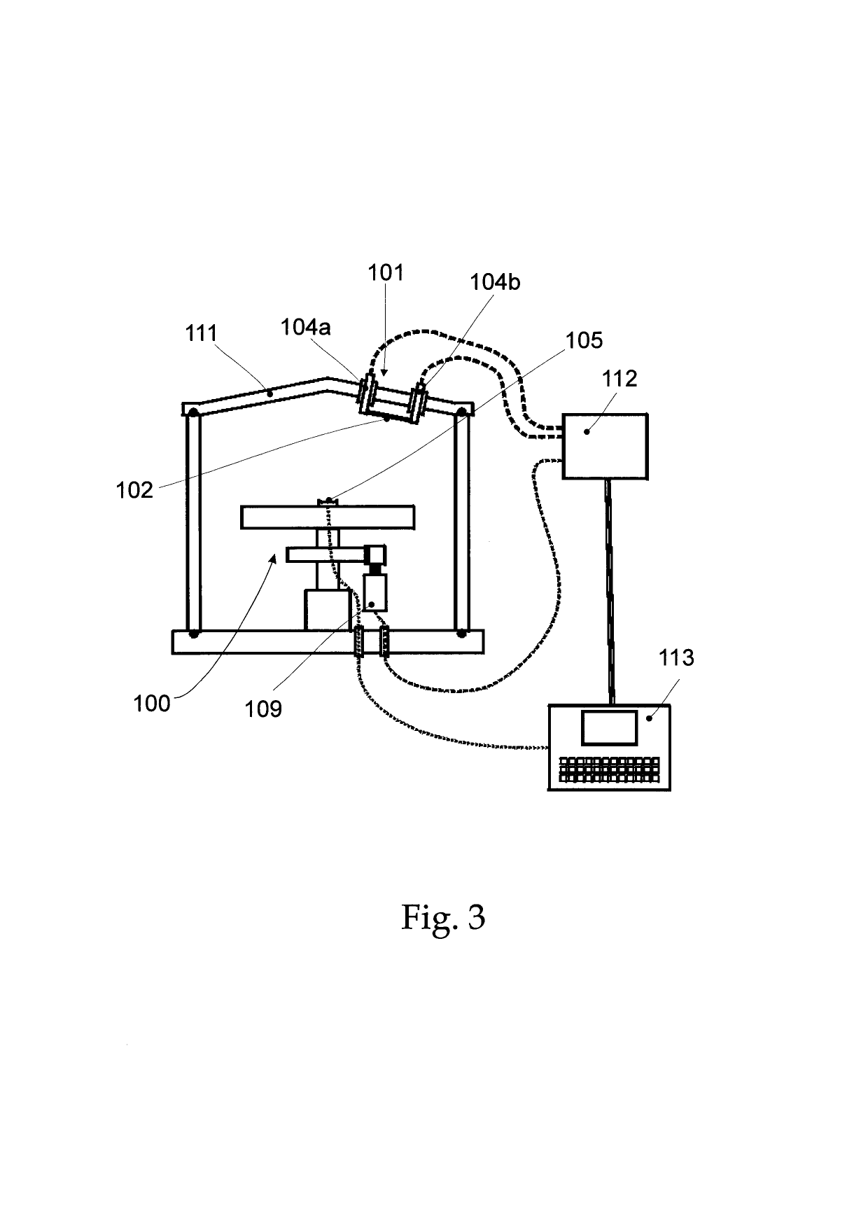

FIG. 1 schematically depicts an arrangement having a motorized sample stage 100 associated with apparatuses according to the present invention, which is arranged eccentrically with respect to an evaporation source 101 for a carbon thread 102. The sample stage and evaporation source 101 in vacuum chamber 111 (depicted in FIG. 3) can be arranged in vacuum chamber 111 physically separated from one another in a manner known per se by means of a pivotable “shutter” (not depicted), the pivotable shutter being pivoted away upon evaporation of the carbon thread. Sample stage 100 and evaporation source 101 are arranged in a vacuum chamber 111 in which, after it is evacuated, a vacuum of better than 1×10⁻² mbar is intended to exist. Electron microscopy samples or specimens 103a-d are positioned on sample stage 100 in sample holders (not depicted in further detail). Samples 103a-d are located at a distance of 30 mm to 100 mm from evaporation source 101. Evaporation source 101 shown in FIG. 1 comprises two electrical feedthroughs 104a, 104b that have control applied to them by an electronic control system 112 (see FIG. 3), so that carbon thread 102 that is received between electrical feedthroughs 104a, 104b can be heated by a large current and thereby evaporated.

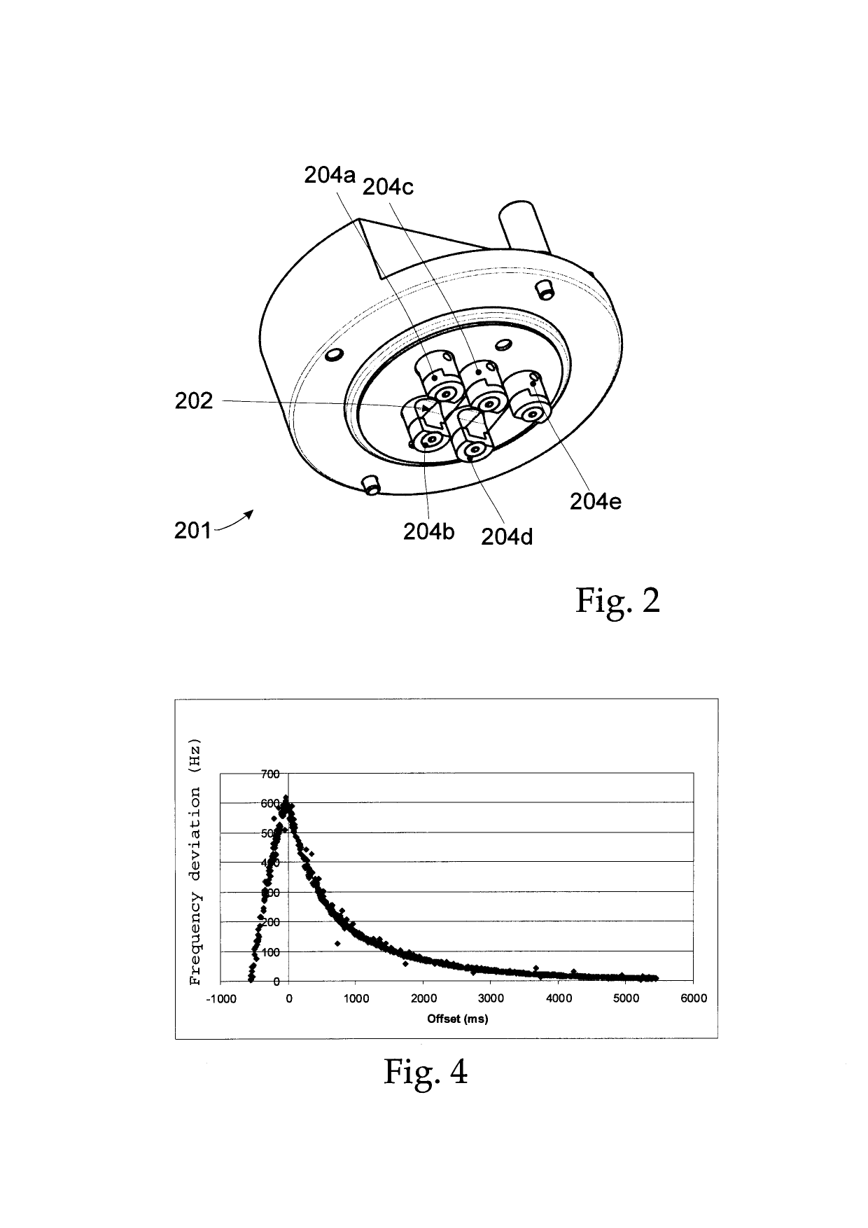

FIG. 2 shows a further embodiment of an evaporation source 201 having five electrical feedthroughs 204a-e. Evaporation source 201 can be used alternatively to evaporation source 101 shown in FIG. 1. A carbon thread 202 is threaded through between electrical feedthroughs 204a-e. This results, in the example shown, in a total of four carbon thread segments; the electronic control system applies control in each case to one adjacent pair of feedthroughs 204a-e, so that only one thread segment is in each case energized and evaporated. Evaporation source 201 is preferably arranged displaceably in the vacuum chamber in such a way that the respective thread segment to be evaporated is positioned in an evaporation position at a suitable spacing from the sample. When the resistance of a thread segment has become so high, as a result of evaporation of the material, that the current flow is no longer sufficient for further evaporation, operation switches to a different, as yet unused thread segment. In an advantageous embodiment, source holder 201 or sample stage 100 can be displaced in motorized fashion so that the geometric offset of the thread segments can be equalized.

Returning to FIG. 1, a quartz oscillator 105, with which the thickness of a deposited layer can be determined by way of the change in resonant frequency, is arranged in the immediate vicinity of samples 103a-d at the center of sample stage 100. The quartz oscillator is implemented, for example, as a measurement head fitted with a suitable quartz wafer. The quartz wafer is preferably one having an AT orientation. The measurement head can also be arranged in a different geometrically favorable position, for example directly nest to the outer periphery of the sample stage, if the center of the table is needed for the reception of samples.

Electronic control system 112 sends current pulses through carbon threads 102 in order to heat them so that the thread segment only partly evaporates and does not under any circumstances break. In the example shown, the pulse data are selected so that for each thread segment at least two, preferably more, current pulses can be carried out before the resistance of the thread has become so high, as a result of evaporation of the evaporation material, that the current flow is no longer sufficient for further evaporation. The pulse data depend on the thread material used, and encompass pulse lengths from 20 ms to 1 s, preferably 50 ms to 500 ms, and currents from 6 A to 50 A. Electronic control system 112 can regulate the current by current limiting upon application of a maximum voltage, by direct current regulation, or by adaptive adjustment of the voltage to the resistance measured in the preceding current pulse.

Sample stage 100 is embodied as a switchable stage movable by a motor, and comprises a turntable 106, rotatable around a rotation axis L, that is rotatably mounted in vacuum chamber 111 on a shaft 108 by means of a bearing 107. Samples 103a-d are preferably arranged on turntable 106 offset at identical angles from one another, although functionality of the method disclosed is guaranteed even in the context of an irregular or stochastic arrangement of the samples. Turntable 106 is movable by means of a motor 109 via a conversion drive 110. The positions of samples 103a-d with reference to evaporation source 101 can be changed by means of the rotary motion, so that the layer distribution determined by the evaporation geometry can be equalized. The result is that a larger number of samples can be uniformly coated with a coating of well-defined layer thickness. The change in positions usually occurs after each current pulse. The pulse data are usefully selected so that for each thread segment, the number of current pulses carried out is sufficient that each of the samples arranged on turntable 106 is vapor-coated with the same number of current pulses.

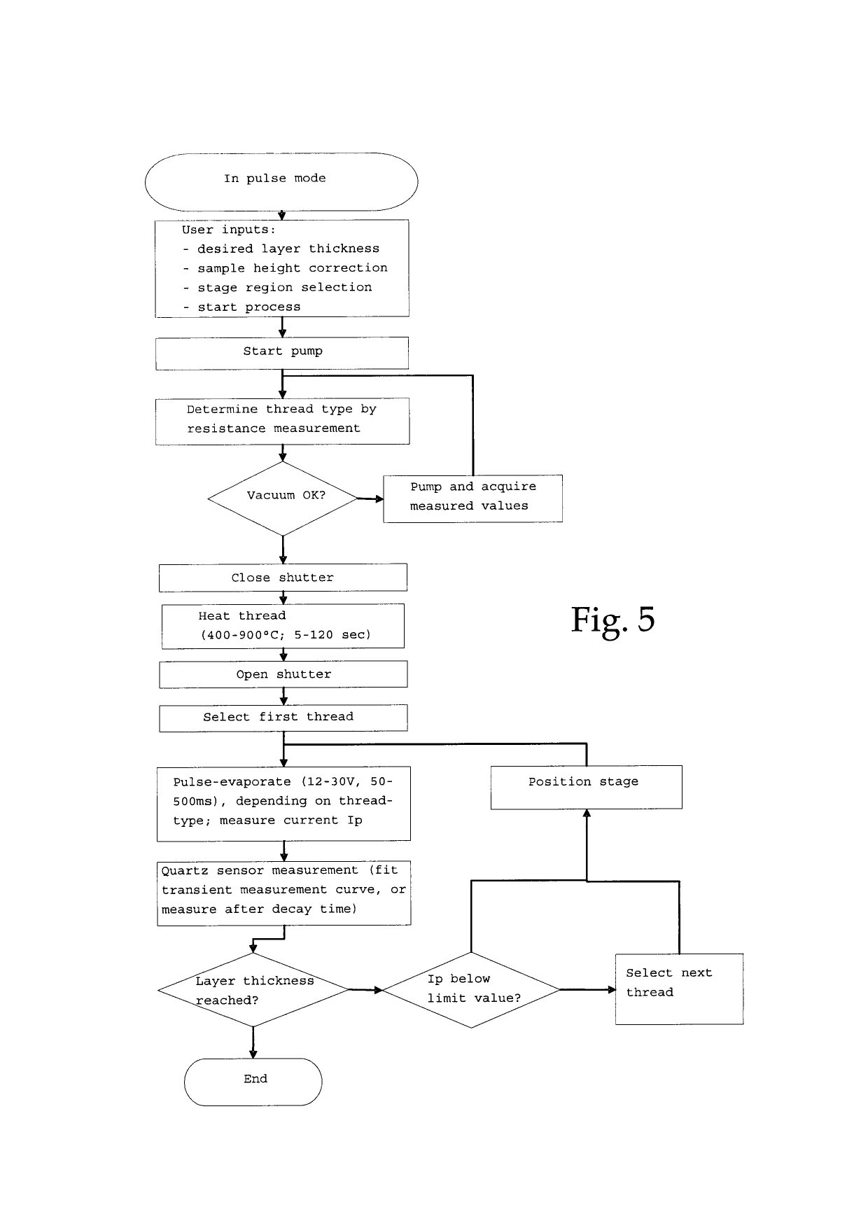

FIG. 3 schematically depicts the arrangement of FIG. 1, sample stage 100 and evaporation source 101 being arranged in a vacuum chamber 111. The two electrical feedthroughs 104a, 104b have control applied to them via an electronic control system 112 so that carbon thread 102 that is received between electrical feedthroughs 104a, 104b can be heated by a large current and thereby evaporated. Motor 109 also has control applied to it by electronic control system 112 in order to position the samples arranged on motorizedly movable sample stage 101 with respect to evaporation source 101 as described above. The deposited material layer thickness is identified by means of an evaluation device 113, the transient decay behavior of quartz oscillator 105 being taken into account as described in detail below in FIGS. 4 and 5. The signal connections between the individual components are depicted as dashed lines.

FIG. 4 shows a decay function of a quartz oscillator, depicting the frequency deviation integrated over gate time plotted against the offset (ms) of the gate time with respect to the current pulse. The decay function shown in FIG. 4 was plotted with a quartz oscillator having an AT orientation. A quartz oscillator typically oscillates at a frequency of 5 to 6 MHz. The deposition of material (in the example shown, carbon) results in a change in the resonant frequency of the quartz oscillator. The difference between the baseline level of the quartz oscillator signal sensed before deposition of the carbon layer and the baseline level of the quartz oscillator signal after deposition of the carbon layer is in the Hz region; for example, the measured difference for a carbon layer 1 nm thick is typically approx. 15 Hz. The signal of the quartz oscillator is strongly influenced during the current pulse by the emitted radiation (light and heat), and is visible in FIG. 4 as a steep rise in the frequency deviation. As is clearly evident from FIG. 4, this influence decays to a baseline level after approx. 4 to 5 seconds. This baseline level is in turn compared with the baseline level measured after the next current pulse. According to the present invention, this influence is taken into account for an accurate measurement of the thickness of the deposited layer, utilizing the transient decay behavior of the quartz oscillator after completion of a current pulse.

In the context of a first possibility, the signal of the quartz oscillator is allowed to decay to a baseline level before the material layer thickness is measured. This baseline level is usually reached 4 to 5 seconds after completion of the current pulse. Usefully, the material layer thickness is identified from the difference between the baseline level of the quartz oscillator signal before deposition of the material layer and the baseline level of the quartz oscillator signal after deposition of the material layer.

Alternatively thereto, in the context of a second possibility for determining layer thickness, the layer thickness is derived by fitting the transient decay function (transient measured curve), with the result that a sufficiently accurate measurement can already be achieved during the decay time.

FIG. 5 is a flow chart to illustrate a process sequence for coating by means of carbon thread evaporation. Thanks to the procedure depicted in the process sequence, an ideally homogeneous distribution of evaporation material on all sample surfaces is obtained. The process proceeds as follows:
Placing the samples, advantageously in a uniform distribution, on the sample stage (see sample stage 100 in FIG. 1) or in the desired portion of the sample stage.
Clamping the carbon thread in the evaporation source (at least one thread segment as in FIG. 1, or multiple, e.g. up to four, thread segments as depicted in FIG. 2).
Setting control of carbon fiber evaporation to pulse mode.
User inputs:
   desired layer thickness
   sample height correction
   selecting stage portion (entire stage, 180° portion, 90° portion, no rotation)
Closing vacuum chamber and start vacuum pump to pump down until desired vacuum is achieved.
Automatically determining occupied thread positions and thread types by measuring resistance, thereby defining further process parameters.
Closing shutter.
Cleaning thread segments by heating to 400 to 900° C. (as known per se, based on specification from table depending on measured resistance).
Opening the shutter.
Evaporating carbon fiber segments using short current pulses:
   Voltage: 12 to 30 V depending on thread type.
   Pulse length: 50 to 500 ms.
   After each current pulse, a measurement of the deposited layer thickness is carried out using a quartz sensor (e.g. conventional usual quartz oscillator, preferably in AT orientation), taking into account transient decay behavior of quartz oscillator as described above.
   Rotating sample stage into predefined orientation positions to ensure uniform deposition onto all samples, for example:
      For selection of entire stage: 9 positions at angular distance of 40° are cycled through in the sequence 1-4-7-2-5-8-3-6-9, as long as the current flow indicates evaporation of the present thread segment.
      For selection of stage portions: correspondingly fewer or more closely space positions; selection always such that deposition at every point in time is maximally equalized over the selected portion.
      When the resistance of the present thread segment allows no further evaporation: changeover to the next thread segment, readjusting the stage to correct geometric offset of the two threads, then continuing evaporation process until desired layer thickness and layer homogeneity are reached.
      Computational identification of effective homogeneous layer thickness based on thickness measurements, and termination of process when the desired layer thickness is reached.
Optional: Automatically venting chamber at end of the process, if desired.

What is claimed is:

1. An apparatus for depositing a material layer on a sample inside a vacuum chamber, comprising:
a sample stage (100) for arranging at least one sample (103a, 103b, 103c, 103d);
an evaporation source (101, 201), connected to a current source, for a thread-shaped evaporation material (102, 202);
a quartz oscillator (105) for measuring the deposited material layer thickness;
an evaluation device (113) associated with the quartz oscillator (105); and
an electronic control system (112) associated with the evaporation source (101, 201);
wherein the electronic control system is configured to deliver to the evaporation source (101, 201) the electric current provided by the current source in at least two current pulses each having a pulse length less than or equal to 1 s; and
wherein the evaluation device (113) is configured to take into account a transient decay behavior of the quartz oscillator (105) immediately after completion of each current pulse in order to derive the material layer thickness deposited after each current pulse.

2. The apparatus according to claim 1, wherein the sample stage (100) is embodied as a switchable stage movable by a motor for positioning the at least one sample with reference to a position of the evaporation source (101, 201)

3. The apparatus according to claim 2, wherein the sample stage (100) comprises a turntable (106) rotatable around a rotation axis (L), at least two samples (103a, 103b, 103c, 103d) being angularly spaced from one another on the rotatable turntable (106).

4. The apparatus according to claim 3, wherein the quartz oscillator (105) is arranged at a center of the turntable (106).

5. The apparatus according to claim 1, wherein the evaporation source (101, 201) comprises a holder, comprising at least two electrical feedthroughs (104a, 104b, 204a, 204b, 204c, 204d, 204e), for the thread-shaped evaporation material (102, 202).

6. The apparatus according to claim 5, wherein the holder for the thread-shaped evaporation material comprises at least three electrical feedthroughs (204a, 204b, 204c, 204d, 204e).

7. The apparatus according to claim 6, wherein the holder for the thread-shaped evaporation material comprises at least five electrical feedthroughs (204a, 204b, 204c, 204d, 204e).

8. The apparatus according to claim 1, wherein at least one sample is arranged at a distance of 30 mm to 100 mm from the evaporation source.

9. The apparatus according to claim 1, wherein the thread-shaped evaporation material is a carbon thread.

10. A method for depositing a material layer on at least one sample inside a vacuum chamber, comprising the steps of:
evaporating at least a segment of a thread-shaped evaporation material by heating by means of electric current, the current being delivered to the thread-shaped evaporation material in at least two current pulses each having a pulse length less than or equal to 1 s, the current pulses being selected so that the thread-shaped evaporation material does not break; and
measuring the material layer thickness deposited after a current pulse of the at least two current pulses by means of a quartz oscillator, taking into account the transient decay behavior of the quartz oscillator immediately after completion of the associated current pulse.

11. The method according to claim 10, wherein measurement of the material layer thickness occurs immediately after completion of each current pulse of the at least two current pulses.

12. The method according to claim 10, wherein the signal of the quartz oscillator is allowed to decay to a baseline level before the material layer thickness is measured.

13. The method according to claim 12, wherein the material layer thickness is determined from a difference between the baseline level of the quartz oscillator signal before deposition of the material layer and the baseline level of the quartz oscillator signal after deposition of the material layer.

14. The method according to claim 10, wherein measurement of the material layer thickness comprises the steps of:
measuring a curve for the frequency of the quartz oscillator as a function of time,
adapting to the curve a parameterized function that is parameterized with at least one parameter, and
deriving the material layer thickness from the at least one parameter.

15. The method according to claim 10, wherein the thread-shaped evaporation material is a carbon thread.

16. The method according to claim 10, wherein the pulse length of a current pulse of the at least two current pulses is in a range of 20 ms to 1 s.

17. The method according to claim 16, wherein the pulse length of the current pulse of the at least two current pulses is in a range of 50 ms to 500 ms.

18. The method according to one of claim 10, wherein the current intensity of a current pulse of the at least two current pulses is from 6 A to 50 A.

19. The method according to one of claim 10, further comprising the step of changing a position of the at least one sample with respect to the thread-shaped evaporation material.

20. The method according to claim 19, wherein a material layer is deposited on two or more samples simultaneously.

21. The method according to claim 19, wherein the step of changing position occurs between two successive current pulses of the at least two current pulses.

22. The method according to claim 10, wherein the method is carried out using the apparatus according to claim 1.
